(19) United States
(12) Patent Application Publication
(10) Pub. No.: US 2026/0293248 A1
(43) Pub. Date: Sep. 24, 2026

(54) SEMICONDUCTOR DEVICE AND METHOD FOR MANUFACTURING THE SAME

(71) Applicant: SONY SEMICONDUCTOR SOLUTIONS CORPORATION, Kanagawa (JP)

(72) Inventor: Naohiko KIMIZUKA, Kanagawa (JP)

(73) Assignee: SONY SEMICONDUCTOR SOLUTIONS CORPORATION, Kanagawa (JP)

(21) Appl. No.: 19/100,623

(22) PCT Filed: Jul. 27, 2023
(86) PCT No.: PCT/JP2023/027502

§ 371 Date: Feb. 3, 2025

(30) Foreign Application Priority Data
Aug. 10, 2022 (JP) 2022-127734

(51) Int. Cl. H10D 62/17; H10D 30/01; H10D 30/62; H10F 39/00

(52) U.S. Cl. CPC H10D 62/235; H10D 30/024; H10D 30/6211; H10F 39/80377

(57) ABSTRACT

The present disclosure relates to a semiconductor device capable of achieving both suppression of a short channel effect and an increase in driving capability, and a method for manufacturing the semiconductor device. The semiconductor device includes: a field effect transistor having a source region and a drain region formed in a semiconductor substrate; and a gate electrode including a planar electrode portion formed in a plane higher than the semiconductor substrate, and two dug-in electrode portions that are dug in the semiconductor substrate. The shape of a channel portion between the two dug-in electrode portions of the field effect transistor is formed asymmetrically in the direction of the source region and the drain region. The present disclosure can be applied to an amplification transistor or the like of each pixel of a solid-state imaging device, for example.

### TECHNICAL FIELD

The present disclosure relates to a semiconductor device and a method for manufacturing the semiconductor device, and more particularly, to a semiconductor device capable of achieving both suppression of a short channel effect and an increase in driving capability, and a method for manufacturing the semiconductor device.

### BACKGROUND ART

Field effect transistors in each of which the semiconductor region having a channel formed therein is formed as a three-dimensional structure (non-planar type) are known, and are also called Fin FETs because the shape of the three-dimensional structure is a fin-like shape.

For example, Patent Document 1 proposes a Fin FET in which the fin width (the width of the fin portion) from the source end to the drain end is constant.

### CITATION LIST

### Patent Document

Patent Document 1: Japanese Patent Application Laid-Open No. 2021-15891.

### SUMMARY OF THE INVENTION

### Problems to be Solved by the Invention

In the Fin FET in which the fin width from the source end to the drain end is constant, however, it is not possible to achieve both suppression of the short channel effect and an increase in the driving capability. That is, if the fin width is reduced in order to suppress the short channel effect, the driving capability is degraded at the same time. Conversely, if the fin width is increased in order to increase the driving capability, the short channel effect becomes conspicuous, the variation in threshold voltage widens, and deterioration in linearity also becomes conspicuous.

The present disclosure has been made in view of such circumstances, and aims to achieve both suppression of the short channel effect and an increase in the driving capability.

### Solutions to Problems

A semiconductor device according to a first aspect of the present disclosure is a semiconductor device that includes a field effect transistor including: a source region and a drain region that are formed in a semiconductor substrate; and a gate electrode including a planar electrode portion formed in a plane higher than the semiconductor substrate, and two dug-in electrode portions that are dug in the semiconductor substrate, in which the shape of a channel portion between the two dug-in electrode portions of the field effect transistor is formed asymmetrically in the direction of the source region and the drain region.

A semiconductor device manufacturing method according to a second aspect of the present disclosure is a method that includes: forming, as a gate electrode of a field effect transistor, a planar electrode portion formed in a plane higher than a semiconductor substrate and two dug-in electrode portions dug in the semiconductor substrate; and forming the shape of a channel portion between the two dug-in electrode portions asymmetrically in the direction of a source region and a drain region of the field effect transistor.

In the first and second aspects of the present disclosure, a planar electrode portion formed in a plane higher than a semiconductor substrate and two dug-in electrode portions dug in the semiconductor substrate are formed as a gate electrode of a field effect transistor, and the shape of a channel portion between the two dug-in electrode portions is asymmetrically formed in the direction of a source region and a drain region of the field effect transistor.

The semiconductor device may be an independent device, or may be a module incorporated into another device.

### BRIEF DESCRIPTION OF DRAWINGS

FIG. 1 is views illustrating an example configuration of a MOS transistor as a semiconductor device according to an embodiment of the present disclosure.

FIG. 2 is views for explaining effects of the MOS transistor illustrated in FIG. 1.

FIG. 3 is plan views illustrating modifications of the MOS transistor illustrated in FIG. 1.

FIG. 4 is views for explaining a method for manufacturing the MOS transistor illustrated in FIG. 1.

FIG. 5 is views for explaining the method for manufacturing the MOS transistor illustrated in FIG. 1.

FIG. 6 is a diagram illustrating a schematic configuration of a photodetection device to which the technology according to the present disclosure is applied.

FIG. 7 is a diagram illustrating an example of the circuit configuration of a pixel illustrated in FIG. 6.

FIG. 8 is a block diagram illustrating an example configuration of an imaging apparatus as an electronic device to which the technology of the present disclosure is applied.

FIG. 9 is a diagram illustrating an example of a schematic configuration of an endoscopic surgery system.

FIG. 10 is a block diagram illustrating an example of functional configurations of a camera head and a CCU.

FIG. 11 is a block diagram illustrating an example of a schematic configuration of a vehicle control system.

FIG. 12 is an explanatory diagram illustrating an example of installation positions of an outside-vehicle information detecting section and imaging sections.

### MODE FOR CARRYING OUT THE INVENTION

The following is a description of a mode for carrying out the technology according to the present disclosure (the mode will be hereinafter referred to as an (the) embodiment), with reference to the accompanying drawings. The description will be given in the following order.
1. Example configuration of a MOS transistor
2. Modifications of the MOS transistor
3. Method for manufacturing a MOS transistor
4. Example of application to a photodetection device
5. Example of application to an electronic apparatus
6. Example of application to an endoscopic surgery system
7. Example of application to a mobile structure

Note that, in the drawings to be referred to in the description below, the same or similar portions are denoted by the same or similar reference signs, and explanation thereof will not be repeated as appropriate. The drawings are schematic, and the relationship between the thickness and the planar dimension, the ratio of the thickness of each layer, and the like differ from the actual ones. Furthermore, the drawings may include portions having different dimensional relationships and ratios in some cases.

Furthermore, definition of directions such as upward and downward directions, and the like in the following description is merely the definition for ease of explanation, and does not limit the technical idea of the present disclosure. For example, when an object is rotated by 90° to be observed, the upper and lower sides are changed as the left and right sides, and, when the object is rotated by 180° to be observed, the upper and lower sides are reversed.

### 1. Example Configuration of a MOS Transistor

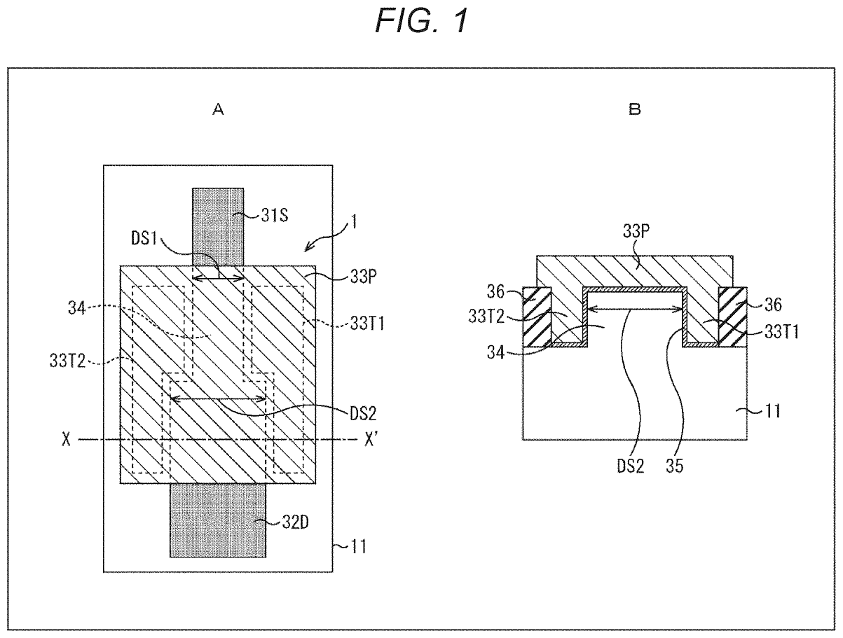

FIG. 1 is views illustrating an example configuration of a metal oxide semiconductor (MOS) transistor as a semiconductor device according to an embodiment of the present disclosure. A of FIG. 1 is a plan view of a MOS transistor, and B of FIG. 1 is a cross-sectional view of the MOS transistor 1 taken along the line X-X′ defined in A of FIG. 1.

The MOS transistor 1 in FIG. 1 is an N-type field effect transistor that has a source region 31S and a drain region 32D formed in a semiconductor substrate 11, and a gate electrode 33 (33P, 33T1, and 33T2) formed between the source region 31S and the drain region 32D.

The semiconductor substrate 11 is formed with a silicon substrate using silicon (Si) as a semiconductor, for example. The source region 31S and the drain region 32D are formed with high-concentration N-type semiconductor regions (diffusion layers) in which high-concentration N-type (first conductivity type) impurity is implanted into the semiconductor substrate 11.

The gate electrode 33 includes a planar electrode portion 33P formed in a plane above the semiconductor substrate 11, and two dug-in electrode portions 33T1 and 33T2 dug in the semiconductor substrate 11. The gate electrode 33 is formed with polysilicon, for example. A region of the semiconductor substrate 11 between the two dug-in electrode portions 33T1 and 33T2 is a channel portion 34 of the MOS transistor 1 that is formed with a P-type (second conductivity type) semiconductor region. The dashed lines of the two dug-in electrode portions 33T1 and 33T2, and the channel portion 34 in between in the plan view in A of FIG. 1 indicate that they are located below the planar electrode portion 33P. The channel portion 34 has a structure in which a width DS1 on the side of the source region 31S and a width DS2 on the side of the drain region 32D are different. In other words, the channel portion 34 has the first width DS1 and the second width DS2 as widths in a direction perpendicular to the direction of the source region 31S and the drain region 32D. In the example in FIG. 1, the width DS2 on the side of the drain region 32D is designed to be greater than the width DS1 on the side of the source region 31S.

As illustrated in the cross-sectional view in B of FIG. 1, a gate insulating film 35 is formed between the semiconductor substrate 11 formed with a P-type semiconductor region and the gate electrode 33. The gate insulating film 35 is formed with a silicon oxide film (SiO2 film), for example. A device separation layer 36 formed with a silicon oxide film (SiO2 film), for example, is formed around the two dug-in electrode portions 33T1 and 33T2. Note that, in the plan view in A of FIG. 1, the gate insulating film 35 and the device separation layer 36 is not shown, for the sake of clarity.

The MOS transistor 1 designed as described above is a field effect transistor having a three-dimensional structure that is a structure in which the two dug-in electrode portions 33T1 and 33T2 sandwich the channel portion 34 via the gate insulating film 35, and is a so-called Fin FET in which the shape of the channel portion 34 is a fin-like shape.

In the MOS transistor 1, as illustrated in the plan view, the shape of the channel portion 34, or specifically, the width of the channel portion 34 is formed asymmetrically in the direction of the source region 31S and the drain region 32D. More specifically, the width DS2 on the side of the drain region 32D is designed to be greater than the width DS1 on the side of the source region 31S.

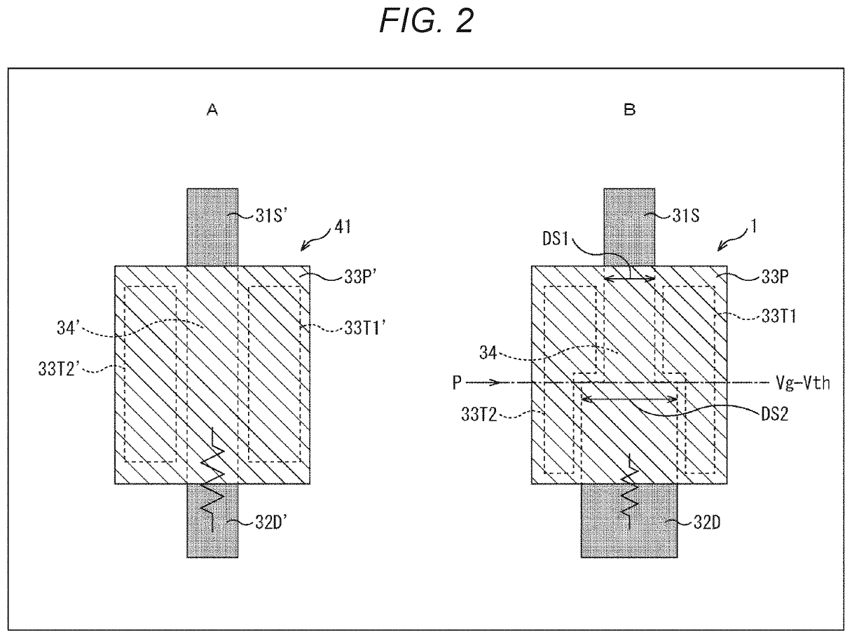

In B of FIG. 2, a switching plane indicated by a dot-and-dash line on which the width of the channel portion 34 is switched from the first width DS1 to the second width DS2 is a pinch-off point P at which the potential of the channel portion 34 is (Vg-Vth), where Vg represents the gate voltage applied to the gate electrode 33 of the MOS transistor 1, and Vth represents the threshold voltage of the MOS transistor 1. Note that the switching plane in which the first width DS1 switches to the second width DS2 may be within a range near the pinch-off point P, or within a range of about ±30 nm from the pinch-off point P in the direction of the source region 31S and the drain region 32D, for example, including manufacturing errors.

A of FIG. 2 illustrates a MOS transistor 41 as a comparative example to be compared with the MOS transistor 1 in FIG. 1. The MOS transistor 41 is a Fin FET that includes a source region 31S′, a drain region 32D′, and a gate electrode 33′ (33P′, 33T1′, and 33T2′) formed between the source region 31S′ and the drain region 32D′, and has a channel portion 34′ formed to have a constant width.

In the case of a Fin FET in which the channel portion 34′ is formed to have a constant width as in the MOS transistor 41 in A of FIG. 2, a drain current Ids is not as large as an effective channel width W, compared with that in a planar MOS transistor. For example, in a case where a planar MOS transistor in which the gate electrode has a channel length L of 560 nm and a channel width W of 240 nm is compared with a Fin FET in which the channel portion 34′ is 80 nm in constant width and 300 nm in constant height, and has a channel length L of 560 nm, which is the same as that of the planar one, the effective channel width W of the Fin FET is 680 nm, which is an effective channel width twice or more the channel width W (=240 nm) of the planar one, but the drain current Ids is not twice larger.

On the other hand, as illustrated in B of FIG. 2, in the MOS transistor 1 in which the width of the channel portion 34 is asymmetrically formed, the width DS2 of the channel portion 34 on the side of the drain region 32D is made greater than the pinch-off point P, so that the volume of the portion where the carriers move due to velocity saturation becomes larger. Thus, the resistance component (parasitic resistance) can be reduced. Furthermore, the contact area between the drain region 32D highly doped with N-type impurity and the channel portion 34 becomes larger, and the resistance component can be reduced accordingly. On the other hand, by reducing the width DS1 of the channel portion 34 on the side of the source region 31S, it is possible to prevent subthreshold characteristics from being affected, or, in other words, to prevent an increase in leakage current Ioff when the transistor is off.

The width DS2 of the channel portion 34 on the side of the drain region 32D can be designed to be at least 10% greater than the width DS1 on the side of the source region 31S, for example.

As described above, the MOS transistor 1 reduces the resistance component inherent in the transistor by increasing the width DS2 of the channel portion 34 on the side of the drain region 32D while maintaining a double-gate effect by reducing the width DS1 on the side of the source region 31S of the channel portion 34. Thus, the MOS transistor 1 can obtain a high driving capability. In other words, since the short channel effect is determined by the width DS1 of the channel portion 34 on the side of the source region 31S, the short channel effect can be suppressed, and both the suppression of the short channel effect and the increase in the driving capability can be achieved.

### 2. Modifications of the MOS transistor

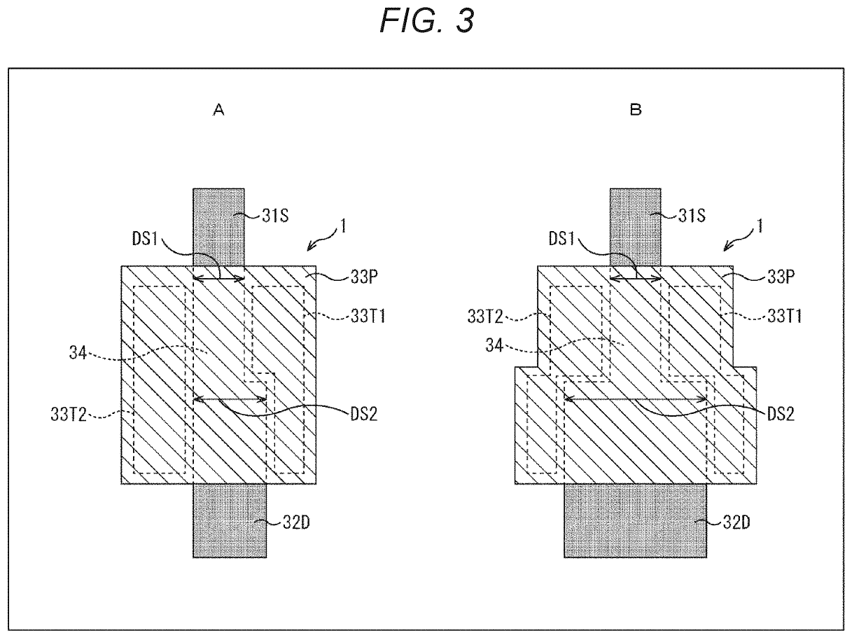

FIG. 3 is plan views illustrating modifications of the MOS transistor 1.

The MOS transistor 1 is only required to have a structure in which the width DS1 of the channel portion 34 on the side of the source region 31S and the width DS2 of the channel portion 34 on the side of the drain region 32D are different from each other, and may have a structure illustrated in A of FIG. 3 or B of FIG. 3.

A MOS transistor 1 according to a first modification illustrated in A of FIG. 3 has a configuration in which one (the left sidewall surface in this example) of sidewall surfaces of the channel portion 34 facing the two dug-in electrode portions 33T1 and 33T2 is the same (flush) plane having no steps, and only the other sidewall surface has a step. In this case, the width DS2 on the side of the drain region 32D is also designed to be greater than the width DS1 on the side of the source region 31S of the channel portion 34.

In a MOS transistor 1 according to a second modification illustrated in B of FIG. 3, the width DS2 of the channel portion 34 on the side of the drain region 32D is designed to be about three times as great as the width DS1 on the side of the source region 31S, and, as the channel portion 34 is enlarged, the two dug-in electrode portions 33T1 and 33T2 on both sides and the planar electrode portion 33P are also formed on the outer side of the side of the source region 31S.

Note that, in order to increase the drain current Ids without changing (without lowering) the threshold voltage Vth, the MOS transistor 1 described above is designed so that the width DS2 on the side of the drain region 32D becomes greater than the width DS1 on the side of the source region 31S.

On the other hand, in a case where it is intended to lower the threshold voltage Vth without changing (without increasing) the drain current Ids, for example, the width DS1 on the side of the source region 31S is only required to be greater than the width DS2 on the side of the drain region 32D, and be formed asymmetrically in the direction of the source region 31S and the drain region 32D.

### 3. Method for Manufacturing the MOS Transistor

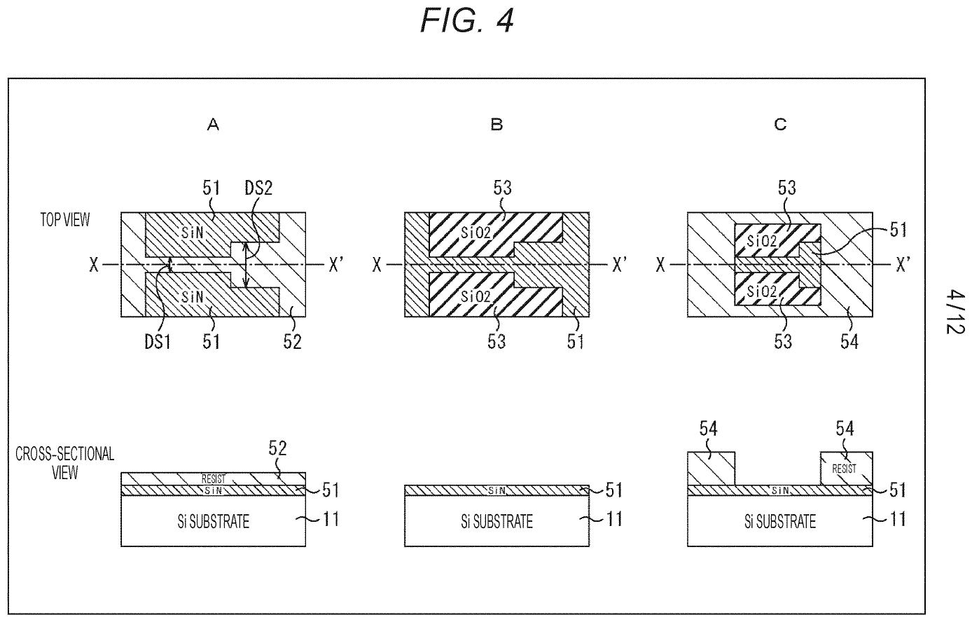

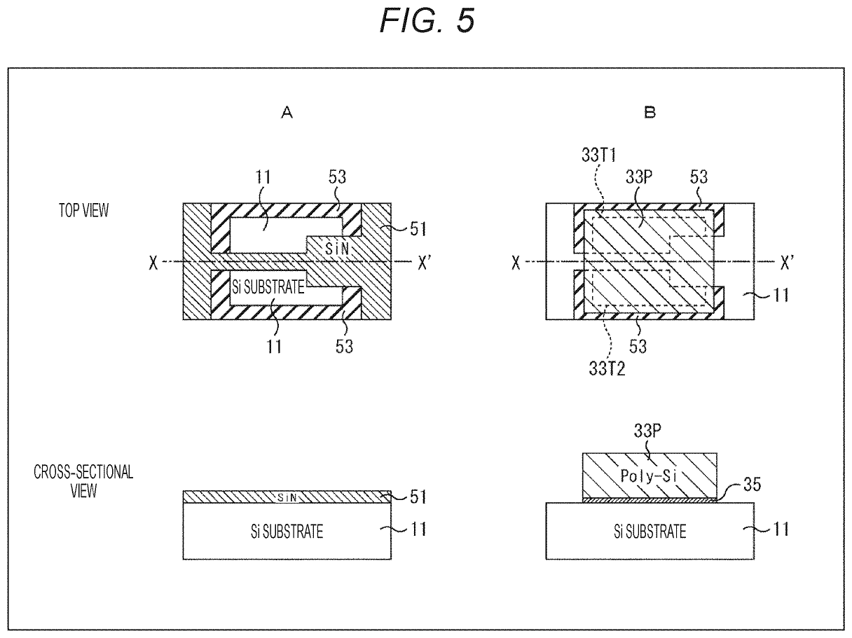

Next, a method for manufacturing the MOS transistor 1 in FIG. 1 is described with reference to FIGS. 4 and 5. FIGS. 4 and 5 show top views and cross-sectional views, and the cross-sectional views are cross-sectional views taken along the line X-X′ defined in the top views.

First, as illustrated in A of FIG. 4, an SiN film 51 is formed on the upper surface as the front surface of a semiconductor substrate (silicon substrate) 11, which is a transistor formation surface, by a CVD method, for example, and patterning is performed on a resist 52 on the SiN film 51 in accordance with the first width DS1 and the second width DS2 of the channel portion 34.

Next, as illustrated in B of FIG. 4, etching is performed with the resist 52 serving as the mask, so that the SiN film 51 is removed, and a trench portion of a predetermined depth is formed in the semiconductor substrate 11 below the SiN film 51. The depth of the trench portion formed in the semiconductor substrate 11 is a depth corresponding to the height of the channel portion 34. After the resist 52 is removed, a silicon oxide film (SiO2 film) 53 that is an insulating film is then buried in the trench portion of the predetermined depth formed in the semiconductor substrate 11. The silicon oxide film 53 is planarized to be flush with the SiN film 51 by chemical mechanical polishing (CMP).

Next, as illustrated in C of FIG. 4, patterning is performed on the resist 54, and the buried silicon oxide film 53 is removed by etching, with the patterned resist 54 serving as the mask.

The state illustrated in A of FIG. 5 is the state in which the resist 54 has been removed after the etching of the silicon oxide film 53. In A of FIG. 5, the semiconductor substrate 11 is exposed at the trench portion from which the buried silicon oxide film 53 has been removed, and the buried silicon oxide film 53 remains in the region outside the trench portion. The remaining silicon oxide film 53 serves as the device separation layer 36.

After the SiN film 51 formed on the upper surface of the semiconductor substrate 11 is removed in A of FIG. 5, the gate insulating film 35 is formed on the surface of the semiconductor substrate 11 by a thermal oxidation method. After that, as illustrated in B of FIG. 5, a polysilicon film is formed on the trench portion of the semiconductor substrate 11 and the upper surface of the semiconductor substrate 11 by a CVD method, for example. Patterning is then performed on the resist (not shown) on the polysilicon film, and the unnecessary portion of the polysilicon film is removed, so that the gate electrode 33 including the two dug-in electrode portions 33T1 and 33T2 and the planar electrode portion 33P is formed.

Lastly, although not illustrated in the drawing, N-type impurity such as phosphorus (P) and arsenic (As) is implanted into predetermined regions of the semiconductor substrate 11 on both sides of the gate electrode 33 in B of FIG. 5, so that the source region 31S and the drain region 32D are formed, and the MOS transistor 1 is completed. The shape of the channel portion 34 of the MOS transistor 1 is formed asymmetrically with respect to the direction of the source region 31S and the drain region 32D.

The MOS transistor 1 in FIG. 1 can be manufactured as described above.

### 4. Example of Application to a Photodetection Device

The above-described MOS transistor 1 in which the channel portion 34 is a Fin FET having at least two widths can be applied to all semiconductor devices having a semiconductor integrated circuit using transistors. In the description below, as an example of a semiconductor device to which the MOS transistor 1 is applied, the configuration of a photodetection device in which each pixel includes a photodiode as a photoelectric conversion unit, a transfer transistor that transfers electric charge generated by the photodiode, and an amplification transistor, for example, will be described.

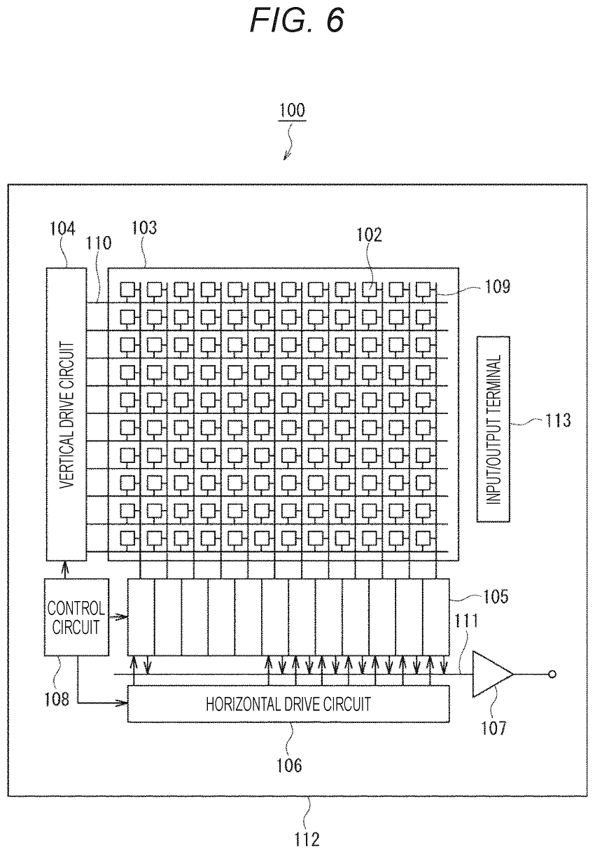

FIG. 6 illustrates a schematic configuration of a photodetection device to which the technology of the present disclosure is applied.

A photodetection device 100 illustrated in FIG. 6 includes a pixel array unit 103 in which pixels 102 are two-dimensionally arranged in a matrix, and a peripheral circuit unit around the pixel array unit 103 on a semiconductor substrate 112 formed with silicon (Si) as a semiconductor, for example. The peripheral circuit unit includes a vertical drive circuit 104, column signal processing circuits 105, a horizontal drive circuit 106, an output circuit 107, a control circuit 108, and the like.

Each pixel 102 in the pixel array unit 103 includes a photodiode unit as a photoelectric conversion unit, a floating diffusion (floating diffusion region), and a plurality of pixel transistors, for example. The plurality of pixel transistors includes four MOS transistors, which are a transfer transistor, a selection transistor, a reset transistor, and an amplification transistor, for example. As at least one of the pixel transistors to be disposed in each pixel 102, the above-described MOS transistor 1 can be adopted.

The pixels 102 may have a shared pixel structure. This shared pixel structure includes a plurality of photodiode units, a plurality of transfer transistors, one shared floating diffusion (floating diffusion region), and one shared other pixel transistor. That is, in the shared pixel structure, photodiodes and transfer transistors that constitute a plurality of unit pixels are designed to share one of other pixel transistors.

The control circuit 108 receives an input clock and data for designating an operation mode or the like, and outputs data such as internal information about the photodetection device 100. That is, the control circuit 108 generates a clock signal and a control signal serving as references for operations of the vertical drive circuit 104, the column signal processing circuits 105, the horizontal drive circuit 106, and the like, on the basis of a vertical synchronization signal, a horizontal synchronization signal, and a master clock. The control circuit 108 then outputs the generated clock signal and control signal to the vertical drive circuit 104, the column signal processing circuits 105, the horizontal drive circuit 106, and the like.

The vertical drive circuit 104 includes a shift register, for example, selects a predetermined pixel drive wiring line 110, supplies a pulse for driving the pixels 102 to the selected pixel drive wiring line 110, and drives the pixels 102 row by row. That is, the vertical drive circuit 104 sequentially selects and scans the respective pixels 102 of the pixel array unit 103 in the vertical direction row by row, and supplies pixel signals based on signal charges generated in accordance with the amounts of received light in the photoelectric conversion units of the respective pixels 102, to the column signal processing circuits 105 through vertical signal lines 109.

The column signal processing circuits 105 are disposed for the respective columns of the pixels 102, and each perform signal processing for each pixel column, such as denoising on signals that are output from one row of the pixels 102. For example, the column signal processing circuits 105 perform signal processing such as correlated double sampling (CDS) for removing pixel-specific fixed pattern noise, and AD conversion.

The horizontal drive circuit 106 includes a shift register, for example, sequentially selects the respective column signal processing circuits 105 by sequentially outputting horizontal scanning pulses, and causes each of the column signal processing circuits 105 to output a pixel signal to a horizontal signal line 111.

The output circuit 107 performs predetermined signal processing on the pixel signals sequentially supplied from the respective column signal processing circuits 105 through the horizontal signal line 111, and outputs the pixel signals. The output circuit 107 may perform only buffering in some cases, for example, or may perform black level adjustment, column variation correction, various kinds of digital signal processing, and the like in other cases. An input/output terminal 113 exchanges signals with the outside.

The photodetection device 100 designed as described above generates signals corresponding to the amounts of light received by the respective pixels 102 of the pixel array unit 103, and outputs the signals to the outside. The photodetection device 100 is a solid-state imaging device that detects a distribution of amounts of incident light of infrared light or visible light, for example, and captures the distribution as an image. Alternatively, the photodetection device 100 may be a light receiving device of a distance measuring system that receives infrared light and measures a distance to a subject by a direct ToF method or an indirect ToF method.

### Example of the Circuit Configuration of a Pixel

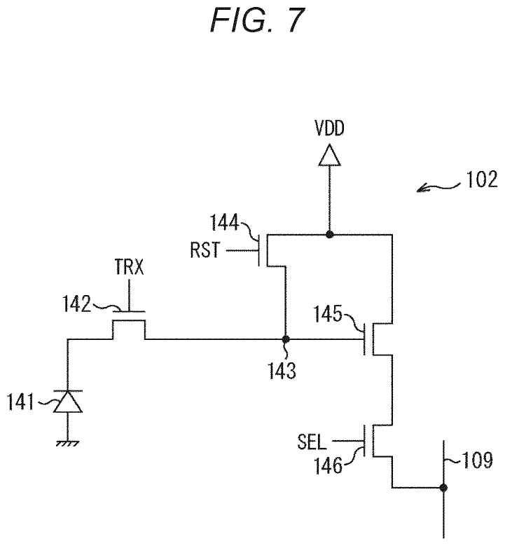

FIG. 7 illustrates an example of the circuit configuration of a pixel 102.

The pixel 102 includes a photodiode 141, a transfer transistor 142, a floating diffusion (FD) 143, a reset transistor 144, an amplification transistor 145, and a selection transistor 146.

The photodiode 141 generates and accumulates charge (signal charge) corresponding to the amount of received light. The photodiode 141 has an anode terminal grounded, and a cathode terminal connected to the FD 143 via the transfer transistor 142.

When turned on by a transfer signal TRX, the transfer transistor 142 reads the charge generated by the photodiode 141, and transfers the charge to the FD 143.

The FD 143 holds the charge read from the photodiode 141. When turned on by a reset signal RST, the reset transistor 144 resets the potential of the FD 143 by discharging the charge accumulated in the FD 143 to the drain (a constant voltage source VDD).

The amplification transistor 145 outputs a pixel signal corresponding to the potential of the FD 143. That is, the amplification transistor 145 forms a source follower circuit with a load MOS (not shown) as a constant current source connected via the vertical signal line 109, and a pixel signal indicating the level corresponding to the charge accumulated in the FD 143 is output from the amplification transistor 145 to the column signal processing circuit 105 via the selection transistor 146.

The selection transistor 146 is turned on when the pixel 102 is selected by a selection signal SEL, and outputs the pixel signal of the pixel 102 to the column signal processing circuit 105 via the vertical signal line 109. Each signal line through which the transfer signal TRX, the selection signal SEL, and the reset signal RST are transmitted corresponds to a pixel drive wiring line 110 in FIG. 6.

The above-described MOS transistor 1 can be adopted as at least one of the transfer transistor 142, the reset transistor 144, the amplification transistor 145, and the selection transistor 146 of such a pixel 102. For example, the MOS transistor 1 can be adopted as the amplification transistor 145. Thus, it is possible to obtain a high driving capability without affecting the subthreshold characteristics.

The pixel 102 is not limited to the above configuration, and some other configuration may be adopted.

### 5. Examples of Application to an Electronic Apparatus

The technology according to the present disclosure can be applied to general electronic apparatuses using a solid-state imaging device as an image capturing unit (a photoelectric conversion unit), such as an imaging apparatus like a digital still camera or a video camera, a portable terminal device having an imaging function, and a copying machine using a solid-state imaging device as an image reading unit. The solid-state imaging device may be formed as one chip, or may be in a module form having an imaging function in which an imaging unit and a signal processing unit or an optical system are packaged together.

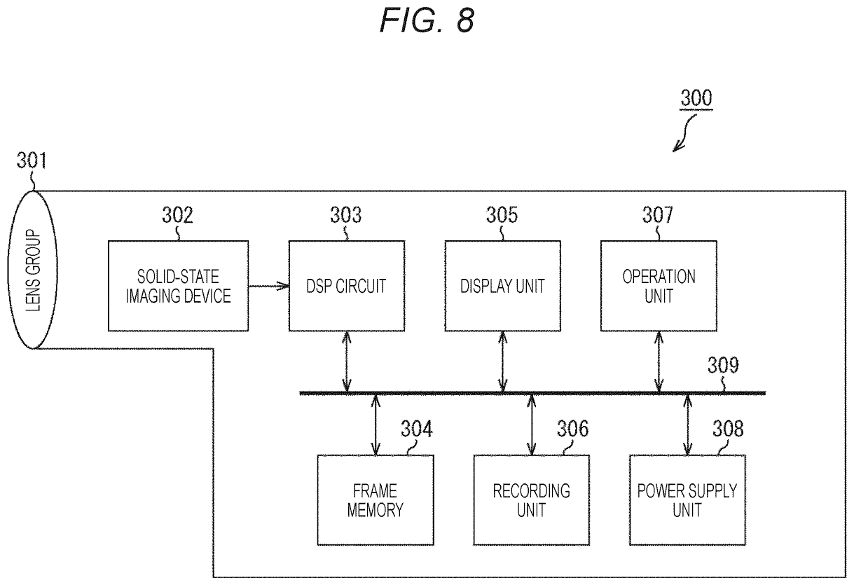

FIG. 8 is a block diagram illustrating an example configuration of an imaging apparatus as an electronic apparatus to which the technology according to the present disclosure is applied.

An imaging apparatus 300 in FIG. 8 includes an optical unit 301 formed with a lens group and the like, a solid-state imaging device (an imaging device) 302 in which the configuration of the photodetection device 100 in FIG. 7 is adopted, and a digital signal processor (DSP) circuit 303 that is a camera signal processing circuit. Also, the imaging apparatus 300 includes a frame memory 304, a display unit 305, a recording unit 306, an operation unit 307, and a power supply unit 308. The DSP circuit 303, the frame memory 304, the display unit 305, the recording unit 306, the operation unit 307, and the power supply unit 308 are connected to one another through a bus line 309.

The optical unit 301 captures incident light (image light) from the subject and forms an image on the imaging surface of the solid-state imaging device 302. The solid-state imaging device 302 converts the amount of the incident light imaged on the imaging surface by the optical unit 301 into an electrical signal for each pixel, and outputs the electrical signal as a pixel signal. As the solid-state imaging device 302, it is possible to use the photodetection device 100 in FIG. 7, which is a device including the pixels 102 in which the MOS transistor 1 having a vertical gate electrode structure including the channel portion 34 with at least two widths as is adopted as a component such as the amplification transistor 145 or the like.

The display unit 305 is formed with a panel-type display device such as a liquid crystal panel or an organic electro luminescence (EL) panel, for example, and displays a moving image or a still image captured by the solid-state imaging device 302. The recording unit 306 records the moving image or the still image captured by the solid-state imaging device 302 on a recording medium such as a hard disk, a semiconductor memory, or some other recording medium.

Being operated by the user, the operation unit 307 issues an operation command regarding various functions of the imaging apparatus 300. The power supply unit 308 supplies various power sources serving as operation power sources for the DSP circuit 303, the frame memory 304, the display unit 305, the recording unit 306, and the operation unit 307, to these supply targets as appropriate.

As described above, by using the photodetection device 100 including the above-described MOS transistor 1 in at least one of the pixel transistors of each pixel as the solid-state imaging device 302, it is possible to achieve both suppression of the short channel effect and an increase in the driving capability. Accordingly, in the imaging apparatus 300 such as a video camera, a digital still camera, or even a camera module for a mobile device such as a portable telephone or the like, the image quality of a captured image can also be increased.

### 6. Example of Application to an Endoscopic Surgery System

The technology according to the present disclosure can be applied to various products. For example, the technology according to the present disclosure may be applied to an endoscopic surgery system.

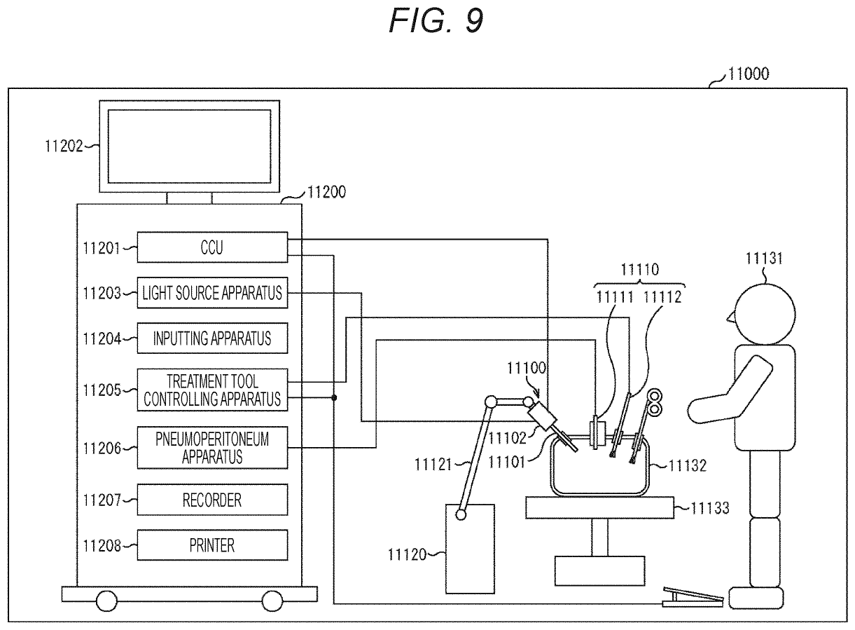

FIG. 9 is a diagram illustrating an example of a schematic configuration of an endoscopic surgery system to which the technology according to the present disclosure (the present technology) can be applied.

FIG. 9 illustrates a state in which a surgeon (medical doctor) 11131 is using an endoscopic surgery system 11000 to perform surgery on a patient 11132 on a patient bed 11133. As depicted, the endoscopic surgery system 11000 includes an endoscope 11100, other surgical tools 11110 such as a pneumoperitoneum tube 11111 and an energy treatment device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 is formed with a light source such as a light emitting diode (LED), for example, and supplies irradiation light for imaging a surgical region or the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the driving of the light source apparatus 11203 may be controlled such that the intensity of light to be output is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band light observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

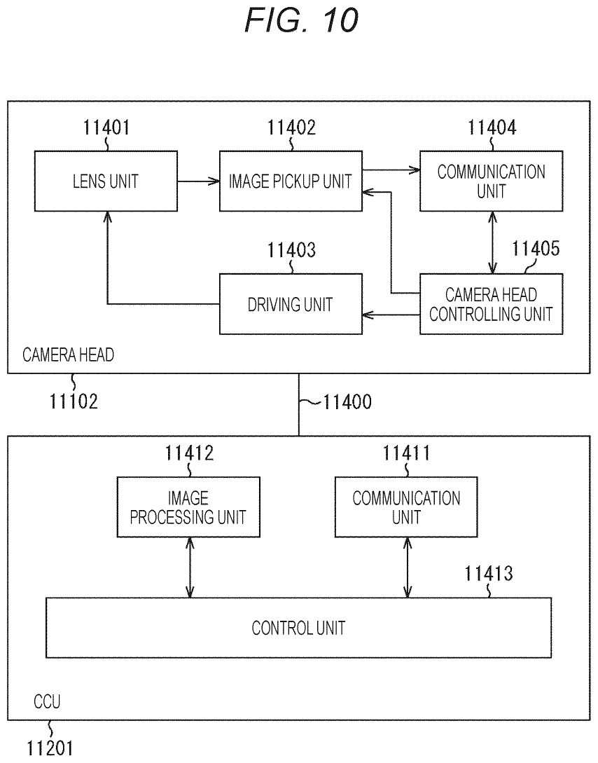

FIG. 10 is a block diagram illustrating an example of functional configurations of the camera head 11102 and the CCU 11201 illustrated in FIG. 9.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals compatible with three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be appropriately designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy treatment device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been described above. The technology according to the present disclosure may be applied to the image pickup unit 11402 of the camera head 11102 among the components described above. Specifically, a solid-state imaging device having pixels among which the MOS transistor 1 is adopted as one or more pixel transistors can be applied as the image pickup unit 11402. By applying the technology according to the present disclosure to the image pickup unit 11402, it is possible to obtain a sharper surgical site image with the camera head 11102 that is smaller in size.

Note that an endoscopic surgery system has been described as an example herein, but the technology according to the present disclosure may be applied to a microscopic surgery system or the like, for example.

### 7. Example of Application to a Mobile Structure

The technology according to the present disclosure can be applied to various products. For example, the technology according to the present disclosure may be embodied in the form of a device to be mounted on a mobile structure of any kind, such as an automobile, an electric vehicle, a hybrid electric vehicle, a motorcycle, a bicycle, a personal mobility, an airplane, a drone, a vessel, or a robot.

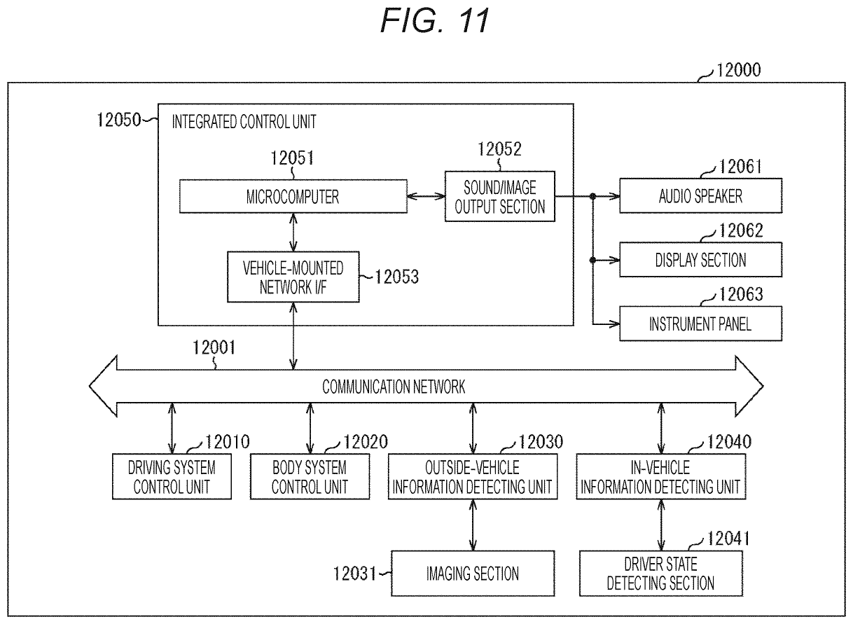

FIG. 11 is a block diagram illustrating an example of a schematic configuration of a vehicle control system as an example of a mobile structure control system to which the technology according to the present disclosure can be applied.

The vehicle control system 12000 includes a plurality of electronic control units connected to each other via a communication network 12001. In the example illustrated in FIG. 11, the vehicle control system 12000 includes a driving system control unit 12010, a body system control unit 12020, an outside-vehicle information detecting unit 12030, an in-vehicle information detecting unit 12040, and an integrated control unit 12050. Further, a microcomputer 12051, a sound/image output section 12052, and a vehicle-mounted network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 11, an audio speaker 12061, a display section 12062, and an instrument panel 12063 are illustrated as an example of output devices. The display section 12062 may, for example, include at least one of an on-board display and a head-up display.

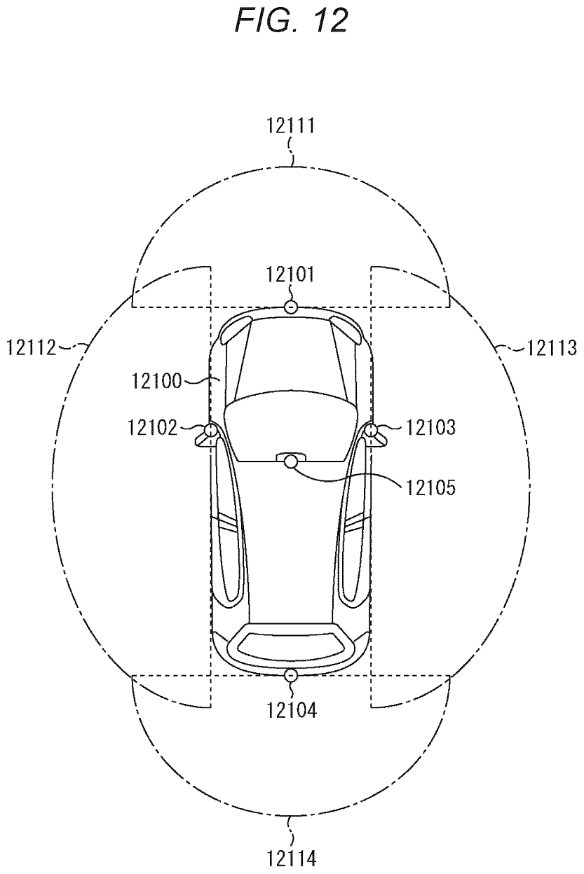

FIG. 12 is a diagram illustrating an example of installation positions of the imaging section 12031.

In FIG. 12, a vehicle 12100 includes imaging sections 12101, 12102, 12103, 12104, and 12105, as the imaging section 12031.

The imaging sections 12101, 12102, 12103, 12104, and 12105 are provided at positions such as the front nose, the sideview mirrors, the rear bumper, the back doors, and an upper portion of the windshield in the interior of the vehicle 12100, for example. The imaging section 12101 provided to the front nose and the imaging section 12105 provided to the upper portion of the windshield within the interior of the vehicle obtain mainly an image of the front of the vehicle 12100. The imaging sections 12102 and 12103 provided on the sideview mirrors obtain mainly images of the sides of the vehicle 12100. The imaging section 12104 provided to the rear bumper or the back door obtains mainly an image of the rear of the vehicle 12100. Forward images to be obtained by the imaging sections 12101 and 12105 are used mainly to detect a preceding vehicle, a pedestrian, an obstacle, a traffic signal, a traffic sign, a lane, or the like.

Note that, FIG. 12 illustrates an example of the imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described above. The technology according to the present disclosure can be applied to the imaging section 12031 among the components described above. Specifically, a solid-state imaging device including pixels in which the MOS transistor 1 is adopted as one or more pixel transistors can be adopted as the imaging section 12031. By applying the technology according to the present disclosure to the imaging section 12031, it is possible to obtain easier-to-view captured images and obtain distance information while reducing the size. Furthermore, it is possible to reduce driver's fatigue and increase the safety of the driver and the vehicle, using the obtained captured images and distance information.

In the above-described example, an N-type MOS transistor in which the first conductivity type is the N-type, the second conductivity type is the P-type, and electrons are used as signal charges has been described. However, the present disclosure can also be applied to a P-type MOS transistor in which holes are used as signal charges. That is, the first conductivity type is the P-type, the second conductivity type is the N-type, and each semiconductor region described above can be formed with a semiconductor region of an opposite conductivity type.

Embodiments of the present disclosure are not limited to the above-described embodiment, and various modifications may be made without departing from the scope of the technique according to the present disclosure.

Note that the effects described in the present specification are merely examples and are not restrictive, and there may be effects other than those described in the present specification.

Note that the technology according to the present disclosure can have the following configurations.

(1)

A semiconductor device including

a field effect transistor including:

a source region and a drain region that are formed in a semiconductor substrate; and

a gate electrode including a planar electrode portion formed in a plane higher than the semiconductor substrate, and two dug-in electrode portions that are dug in the semiconductor substrate,

in which a shape of a channel portion between the two dug-in electrode portions of the field effect transistor is formed asymmetrically in a direction of the source region and the drain region.

(2)

The semiconductor device according to (1),

in which a width of the channel portion in a direction perpendicular to the direction of the source region and the drain region is formed asymmetrically in the direction of the source region and the drain region.

(3)

The semiconductor device according to (1) or (2),

in which the channel portion has a first width and a second width different from the first width, as widths in a direction perpendicular to the direction of the source region and the drain region.

(4)

The semiconductor device according to (3),

in which the second width of the channel portion on the drain region side is designed to be greater than the first width of the channel portion on the source region side.

(5)

The semiconductor device according to (3) or (4),

in which, when a gate voltage of the field effect transistor is represented by Vg, and a threshold voltage is represented by Vth, the width of the channel portion is switched from the first width to the second width at a portion in which a potential of the channel portion is (Vg-Vth).

(6)

The semiconductor device according to (3) or (4),

in which the width of the channel portion is switched from the first width to the second width in a region near a pinch-off point.

(7)

The semiconductor device according to (1),

in which a first width of the channel portion on the source region side is designed to be greater than a second width of the channel portion on the drain region side.

(8)

The semiconductor device according to any one of (1) to (7),

in which the field effect transistor is a pixel transistor of a pixel of a photodetection device that includes a pixel array unit in which a plurality of the pixels is two-dimensionally arranged in a matrix.

(9)

A method for manufacturing a semiconductor device, the method including:

forming, as a gate electrode of a field effect transistor, a planar electrode portion formed in a plane higher than a semiconductor substrate and two dug-in electrode portions dug in the semiconductor substrate; and

forming a shape of a channel portion between the two dug-in electrode portions asymmetrically in a direction of a source region and a drain region of the field effect transistor.

### REFERENCE SIGNS LIST

1 MOS transistor
2 Pixel
11 Semiconductor substrate
31S Source region
32D Drain region
33 Gate electrode
33P Planar electrode portion
33T1 Dug-in electrode portion
34 Channel portion
35 Gate insulating film
36 Device separation layer
100 Photodetection device
102 Pixel
103 Pixel array unit
145 Amplification transistor
300 Imaging apparatus
302 Solid-state imaging device
DS1 First width
DS2 Second width

What is claimed is:

1. A semiconductor device, comprising
a field effect transistor including:
a source region and a drain region that are formed in a semiconductor substrate; and
a gate electrode including a planar electrode portion formed in a plane higher than the semiconductor substrate, and two dug-in electrode portions that are dug in the semiconductor substrate,
wherein a shape of a channel portion between the two dug-in electrode portions of the field effect transistor is formed asymmetrically in a direction of the source region and the drain region.

2. The semiconductor device according to claim 1,
wherein a width of the channel portion in a direction perpendicular to the direction of the source region and the drain region is formed asymmetrically in the direction of the source region and the drain region.

3. The semiconductor device according to claim 1,
wherein the channel portion has a first width and a second width different from the first width, as widths in a direction perpendicular to the direction of the source region and the drain region.

4. The semiconductor device according to claim 3,
wherein the second width of the channel portion on the drain region side is designed to be greater than the first width of the channel portion on the source region side.

515. The semiconductor device according to claim 3,
wherein, when a gate voltage of the field effect transistor is represented by Vg, and a threshold voltage is represented by Vth, a width of the channel portion is switched from the first width to the second width at a portion in which a potential of the channel portion is (Vg-Vth).

6. The semiconductor device according to claim 3,
wherein a width of the channel portion is switched from the first width to the second width in a region near a pinch-off point.

7. The semiconductor device according to claim 1,
wherein a first width of the channel portion on the source region side is designed to be greater than a second width of the channel portion on the drain region side.

8. The semiconductor device according to claim 1,
wherein the field effect transistor is a pixel transistor of a pixel of a photodetection device that includes a pixel array unit in which a plurality of the pixels is two-dimensionally arranged in a matrix.

9. A method for manufacturing a semiconductor device, the method comprising:
forming, as a gate electrode of a field effect transistor, a planar electrode portion formed in a plane higher than a semiconductor substrate and two dug-in electrode portions dug in the semiconductor substrate; and
forming a shape of a channel portion between the two dug-in electrode portions asymmetrically in a direction of a source region and a drain region of the field effect transistor.
